(19) United States
(12) Patent Application Publication
(10) Pub. No.: US 2025/0233070 A1
(43) Pub. Date: Jul. 17, 2025

(54) STACKED TRANSISTORS WITH VERTICAL INTERCONNECT

(71) Applicant: Taiwan Semiconductor Manufacturing Co., Ltd., Hsinchu (TW)

(72) Inventors: Shao-Tse Huang, Hsinchu (TW); Jin-Hao Jhang, Chubei City (TW); Wei-De Ho, Hsinchu (TW)

(21) Appl. No.: 18/667,517

(22) Filed: May 17, 2024

Related U.S. Application Data
(60) Provisional application No. 63/620,325, filed on Jan. 12, 2024.

(51) Int. Cl. H01L 23/528; H01L 21/762; H01L 27/092; H01L 29/06; H01L 29/423; H01L 29/66; H01L 29/775

(52) U.S. Cl. CPC H01L 23/5283; H01L 21/76232; H10D 30/014; H10D 30/43; H10D 30/6735; H10D 62/121; H10D 84/85

(57) ABSTRACT

In an embodiment, a semiconductor device may include a plurality of first nanostructures. The plurality of first nanostructures extend between first source/drain regions. The semiconductor device may also include a plurality of second nanostructures over the plurality of first nanostructures. The plurality of second nanostructures extend between second source/drain regions. The device may furthermore include a first gate stack around the plurality of first nanostructures. The device may in addition include a second gate stack over the first gate stack and disposed around the plurality of second nanostructures. The device may moreover include a vertical interconnect structure extending through the first and second gate stacks. The device may also include a frontside contact electrically coupled to a frontside of the vertical interconnect structure and a backside contact electrically coupled to a backside of the vertical interconnect structure.

### PRIORITY CLAIM AND CROSS-REFERENCE

This application claims the benefit of U.S. Provisional Application No. 63/620,325 filed on Jan. 12, 2024, entitled “Semiconductor Structure with Vertical Local Interconnect and Manufacturing Method Thereof,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example stacking transistor in accordance with some embodiments.

FIGS. 2, 3, 4, 5A, 5B, 6A, 6B, 6C, 7A, 7B, 8A, 8B, 9A, 9B, 9C, 10A, 10B, 10C, 11A, 11B, 12A, 12B, 13A, 13B, 14A, 14B, 14C, 15A, and 15B are views of intermediate stages in the manufacturing of a stacking transistor in accordance with some embodiments.

FIGS. 16A and 16B are views of intermediate stages in the manufacturing of a stacking transistor in accordance with some embodiments.

FIGS. 17A and 17B are views of intermediate stages in the manufacturing of a stacking transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacking transistor, such as a CFET, and the method of forming the same are provided. In various embodiments, the stacking transistor includes two vertically stacked transistors, and a vertical interconnect structure extending through the stacking transistor. The vertical interconnect structure allows for backside interconnect routing and can reduce the need and size of the frontside interconnect. The vertical interconnect structure extends through the stacking transistor in a cut metal gate area of the transistor. Further, the vertical interconnect structure can include a cut region to reduce the capacitance and increase the speed of the device. In some embodiments, the vertical interconnect structure can couple drain regions of the stacking transistor.

The vertical interconnect structure includes a metal interconnect structure and a bottom dielectric structure that reduces the aspect ratio of the metal interconnect structure and avoids a seam or void in the metal interconnect structure. Further, the disclosed embodiments include a backside planarization process to expose the metal interconnect of the vertical interconnect structure without causing the metal interconnect to protrude from the backside. Thus, the disclosed embodiments provide a vertical interconnect structure without metal protrusion from the backside. As a result, the disclosed embodiments allow for improved process integration, increased routing flexibility, and increased device performance.

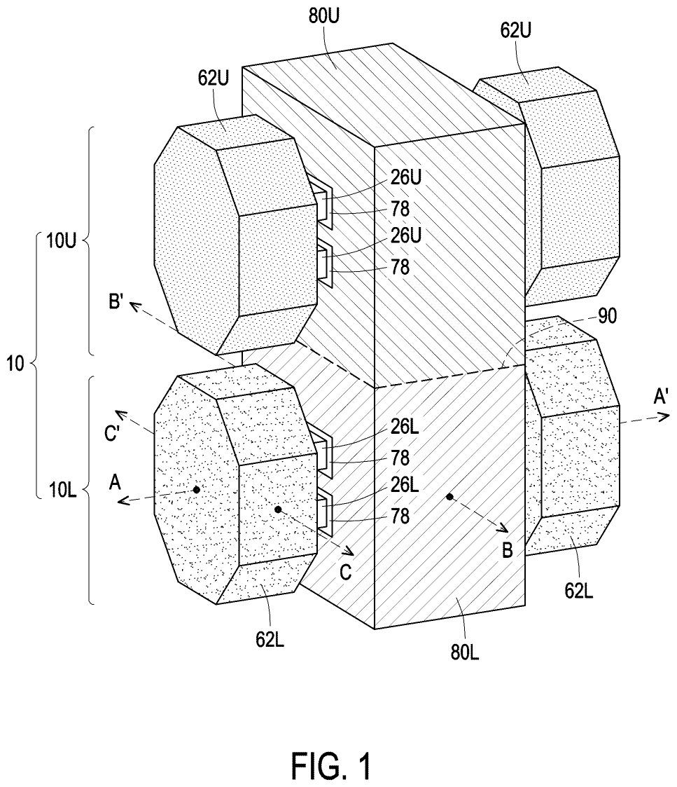

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26 of the stacking transistor 10 and in a direction of, for example, a current flow between the source/drain regions 62 of the stacking transistor 10. Cross-section B-B′ is a vertical cross-section that is perpendicular to cross-section A-A′ and along a longitudinal axis of a gate electrodes 80 of the stacking transistor 10.

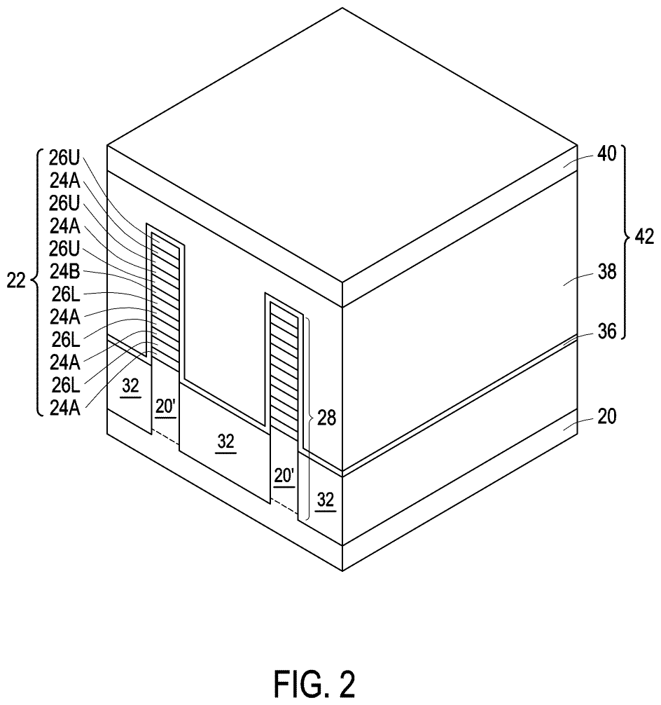

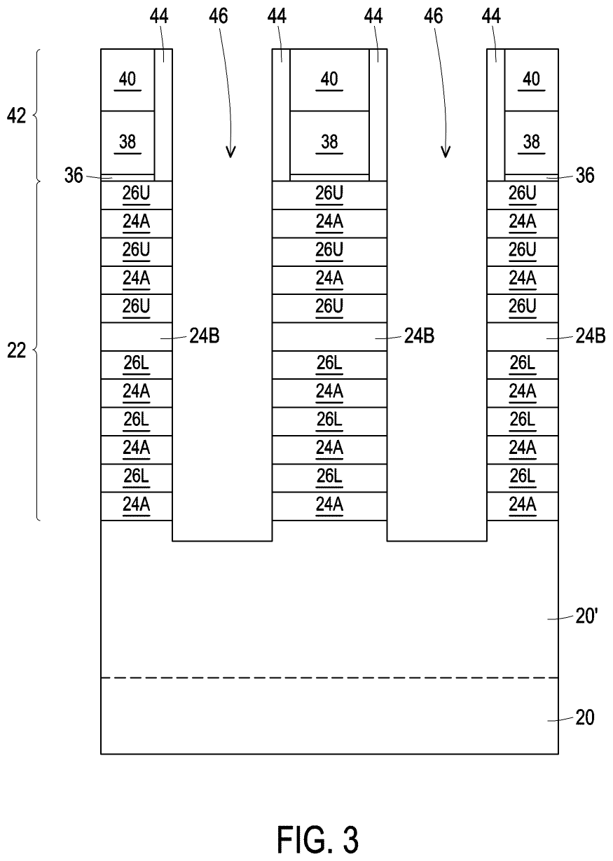

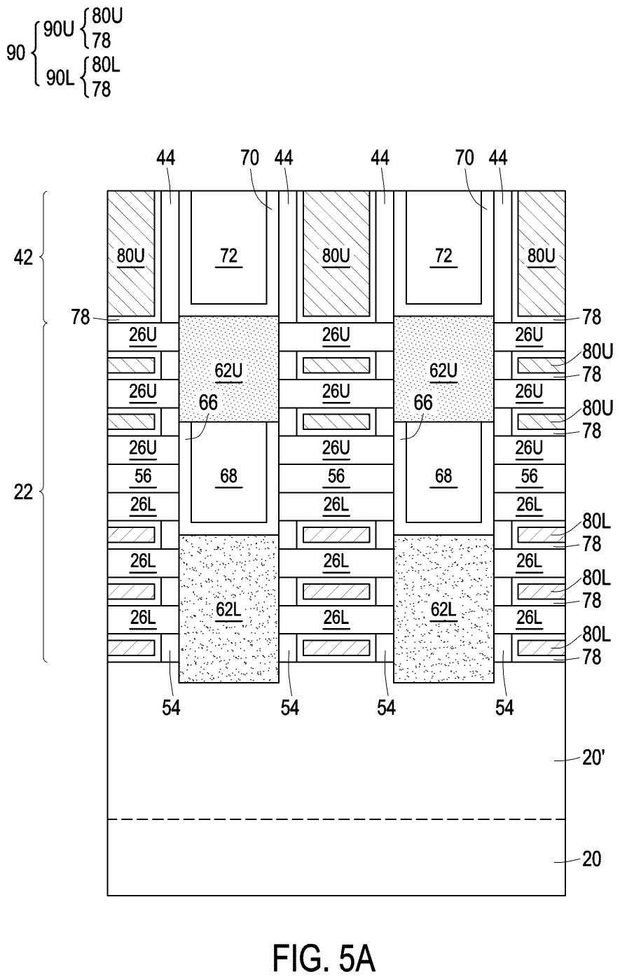

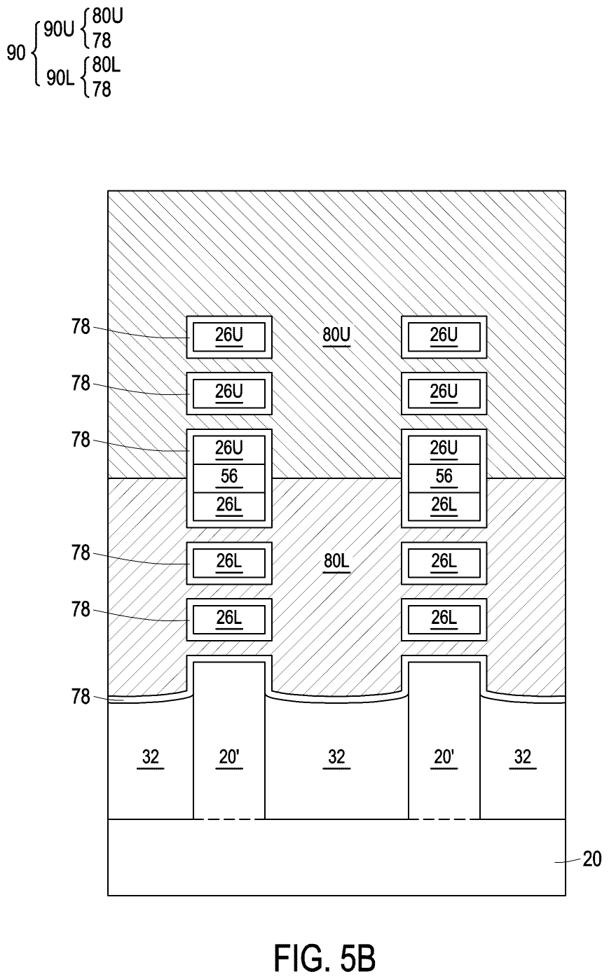

FIGS. 2 through 15B illustrate varying views of intermediate stages in the formation of stacking transistors (as schematically represented in FIG. 1) in accordance with some embodiments. FIG. 2 illustrates a perspective view similar to FIG. 1. FIGS. 3, 4, and 5A illustrate cross-sectional views along a similar cross-section as reference cross-section A-A′ in FIG. 1. FIG. 5B illustrates a cross-sectional views along a similar cross-section as reference cross-section B-B′ in FIG. 1.

In FIG. 2, a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the semiconductor substrate 20. Each of semiconductor strips 28 includes semiconductor strip 20′ (patterned portions of the semiconductor substrate 20, also referred to as a semiconductor fin 20′) and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. Dummy nanostructures 24A and dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy nanostructures 24B may be removed at a faster rate than the dummy nanostructures 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructures 24 may be selectively removed in subsequent process steps without significantly removing the semiconductor nanostructures 26. In some embodiments, the dummy nanostructures 24A are formed of or comprise silicon germanium, the semiconductor nanostructures 26 are formed of silicon, and dummy semiconductor nanostructures 24B may be formed of germanium or silicon germanium with a higher germanium atomic percentage than the dummy nanostructures 24A.

The lower semiconductor nanostructures 26L will provide channel regions for lower nanostructure-FETs of the CFETs. The upper semiconductor nanostructures 26U will provide channel regions for upper nanostructure-FETs of the CFETs. The semiconductor nanostructures 26 that are immediately above/below (e.g., in contact with) the dummy nanostructures 24B may be used for isolation and may or may not act as channel regions for the CFETs. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor fins 20′, the dummy nanostructures 24, and the semiconductor nanostructures 26. The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

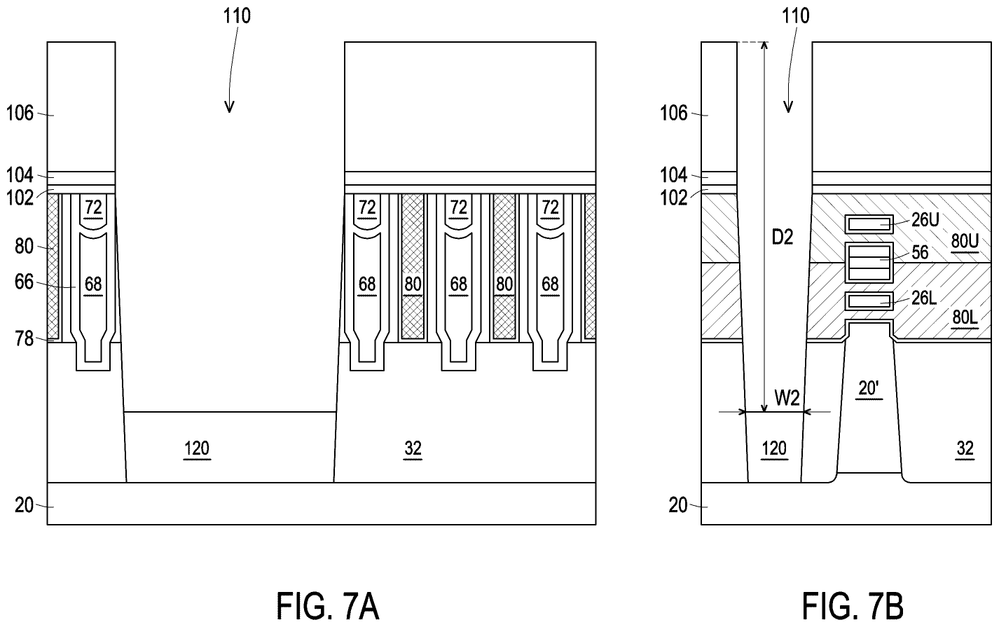

As also illustrated by FIG. 2, shallow trench isolation (STI) regions 32 are formed over the substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) maybe recessed such that upper portions of semiconductor strips 28 (including multi-layer stacks 22) protrude higher than the remaining STI regions 32. Although FIG. 2 illustrates a top surface of the STI regions 32 as being flat, the top surface of the STI regions 32 may be concave (see more detailed drawing of FIGS. 5B and 7) depending on the etching process used to recess the STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22 and into the semiconductor strips 20′. The bottom surfaces of the source/drain recesses 46 may be at a level above, below, or level with the top surfaces of the STI regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

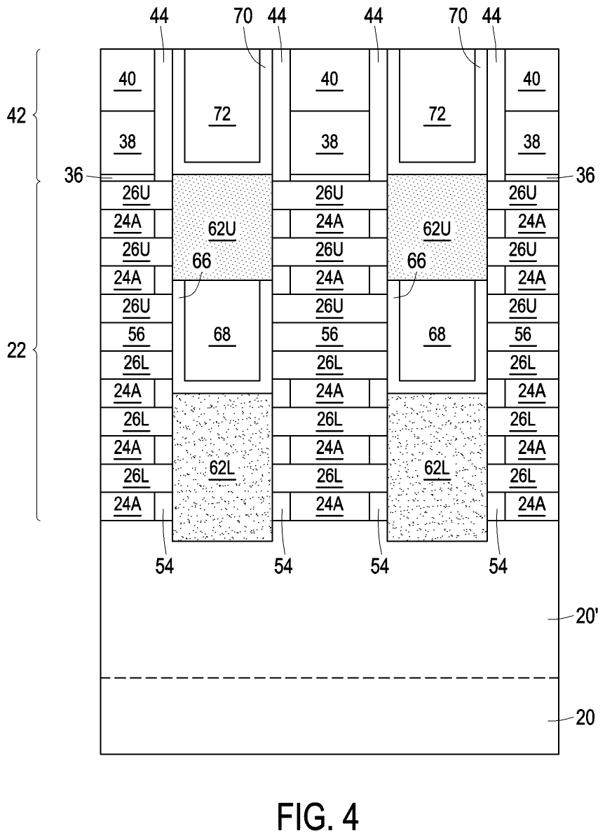

In FIG. 4, inner spacers 54 and dielectric isolation layers 56 are formed. Forming inner spacers 54 and dielectric isolation layers 56 may include an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 warp around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

Inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs.

The inner spacers 54 and the dielectric isolation layers 56 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26U and 26L (thus forming the dielectric isolation layers 56).

As also illustrated by FIG. 4, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. Inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant. Adjacent upper source/drain regions 62U may remain separated after the epitaxy process or may be merged.

After the upper epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for the second CESL 70 and the second ILD 72, and performing a planarization process to remove the excess portion of the corresponding layers. After the planarization process, top surfaces of the second ILD 72, the gate spacers 44, and the masks 40 (if present) or the dummy gate layer 38 are substantially coplanar (within process variations). Accordingly, the top surfaces of the masks 40 (if present) or the dummy gate layer 38 are exposed through the second ILD 72. In the illustrated embodiment, the masks 40 remain after the removal process. In other embodiments, the masks 40 are removed such that the top surfaces of the dummy gate layer 38 are exposed through the second ILD 72.

FIGS. 5A and 5B illustrate different cross-sections of a replacement gate process to replace the dummy gate stacks 42 and the dummy nanostructures 24A with gate stacks 90. FIG. 5A illustrates a cross-sectional view along reference line A-A′ of FIG. 1; and FIG. 5B illustrates a cross-sectional view along reference line B-B′ of FIG. 1. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the dummy nanostructures 24A is etched at a faster rate than the semiconductor nanostructures 26, the dielectric isolation layers 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed dummy gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the semiconductor fins 20′; on the top surfaces, the sidewalls, and the bottom surfaces of the semiconductor nanostructures 26; and on the sidewalls of the gate spacers 44. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The gate dielectrics 78 may be deposited with a conformal deposition process such that portions of the gate dielectrics 78 on the STI regions 32 may have a same profile as an upper surface of the STI regions 32 (e.g., a concave profile as illustrated by FIG. 5B). The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) recessing the gate electrode layer(s). The conformal deposition process for depositing the lower gate electrodes 80L may result in the portions of the lower gate electrodes 80L on the STI regions 32 having a same profile as an upper surface of the STI regions 32 (e.g., a concave profile as illustrated by FIG. 5B). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered upper gate electrodes 80U are illustrated, the upper gate electrodes 80U may include any number of work function tuning layers, any number of barrier layers, any number of glue layers, and a fill material. In some embodiments, the upper gate electrodes 80U may be formed of different materials than the lower gate electrodes 80L. In some embodiments, an interface is visible between the upper gate electrodes 80U and the lower gate electrodes 80L.

Additionally, a removal process is performed to level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20′.

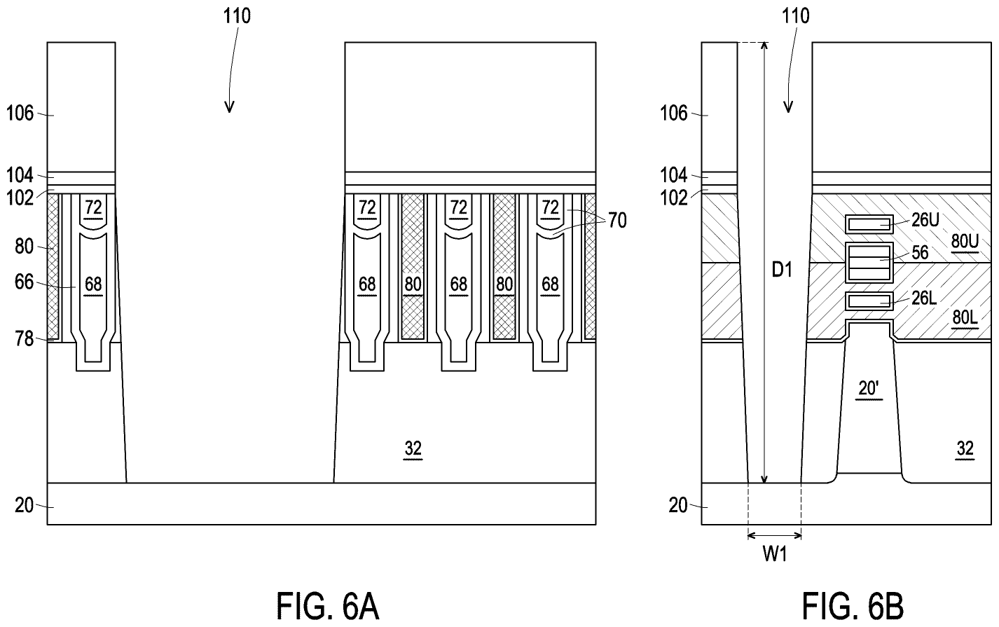

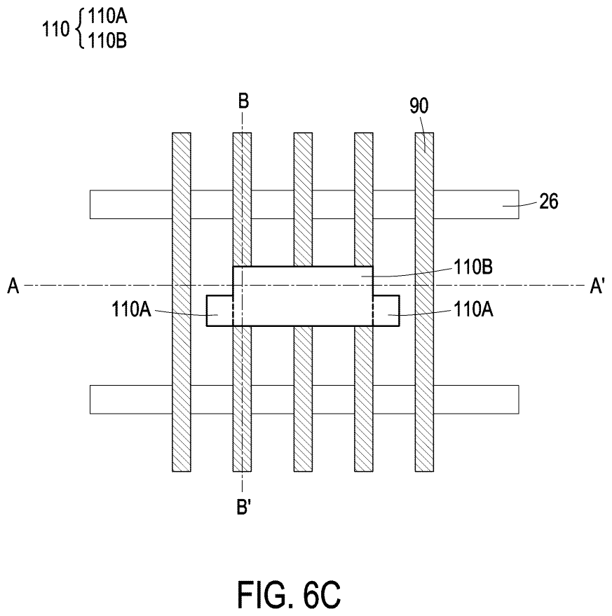

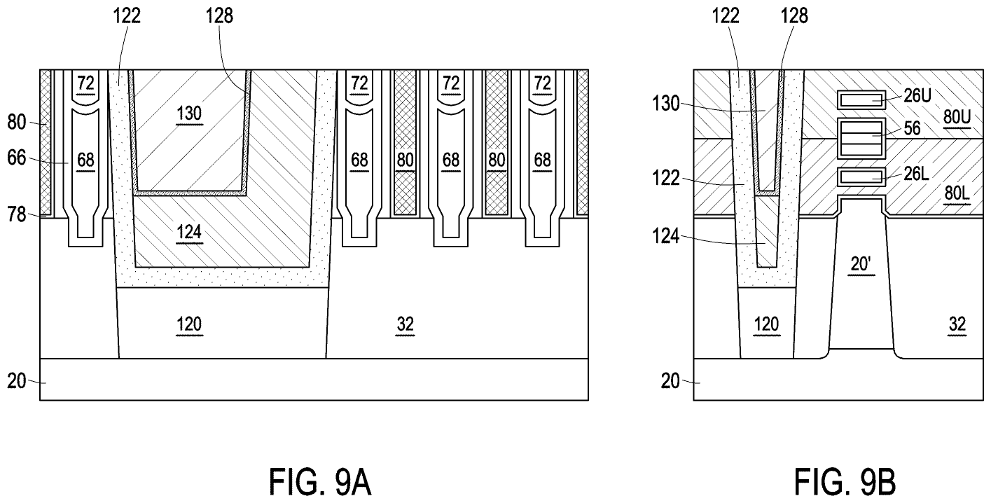

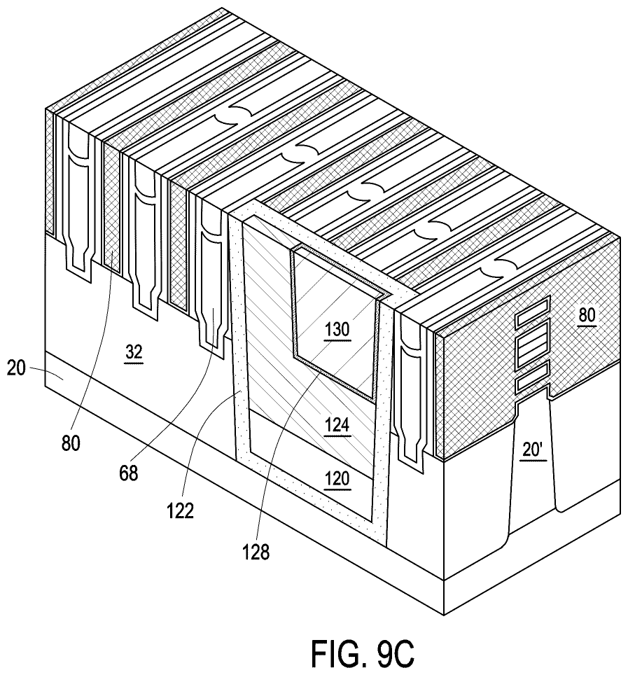

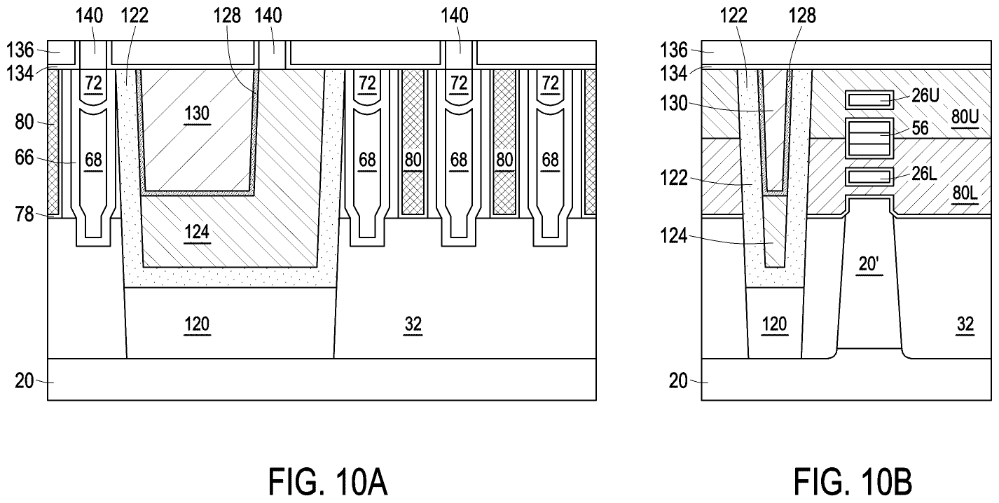

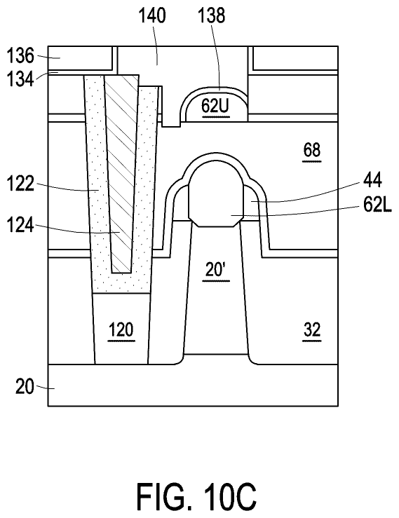

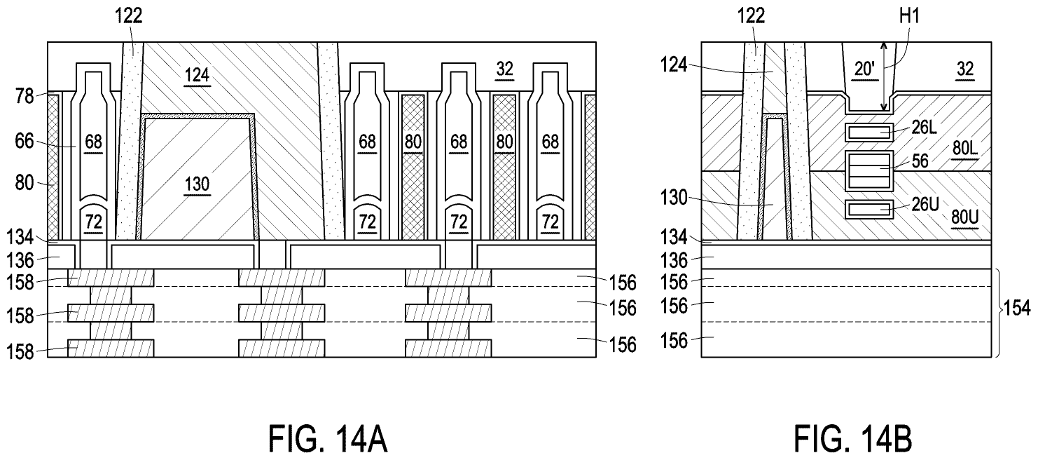

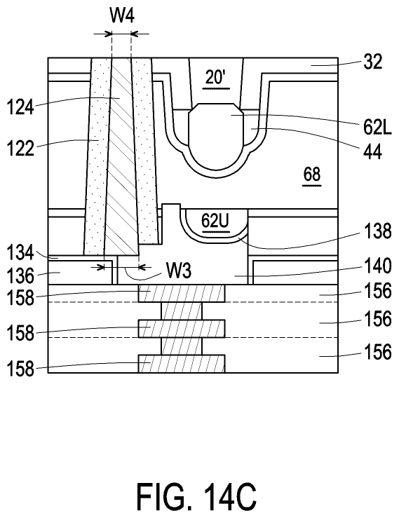

FIGS. 6A, 6B, 6C, 7A, 7B, 8A, 8B, 9A, 9B, 9C, 10A, 10B, 10C, 11A, 11B, 12A, 12B, 13A, 13B, 14A, 14B, 14C, 15A, and 15B illustrate a cut-metal gate process followed by a process for forming contacts and front and back side interconnect structures. Unless specified otherwise, the figures whose numbers having the letter “A” are a cross-sectional view along reference line A-A′ of FIG. 1. The figures whose numbers having the letter “B” are a cross-sectional view along reference line B-B′ of FIG. 1. FIG. 6C is a plan view, FIG. 9C is a perspective view, and FIGS. 10C and 14C are cross-sectional views along reference line C-C′ of FIG. 1.

FIGS. 6A, 6B, and 6C illustrate cutting the gate electrodes 80 (both 80U and 80L) in accordance with some embodiments. After cutting the gate electrodes 80, the gate electrodes 80 will be separated into separate and electrically isolated gate structures 90. While a single gate cut is illustrated, it should be understood that the gate structures 90 may be separated into multiple portions of the gate structure 90 by additional simultaneous cutting processes.

In FIGS. 6A and 6B, hard mask 102, pad layer 104, and hard mask 106 are formed over the gate electrodes 80 and the ILD 72. The material of hard mask 102 may be the same as or different from the materials of some of CESL 66. In some embodiments, the hard mask layer 102 may be formed of a dielectric material having a high etching selectivity from the etching of the second ILD 72, such as silicon nitride, silicon oxide, silicon oxynitride, or the like, which may be formed by any suitable deposition process, such as CVD, ALD, or the like. In some embodiments, the pad layer 104 is formed of a metal-containing material such as TiN, TaN, or the like. Pad layer 64 may also be formed of a dielectric material such as silicon oxide. The material of hard mask 106 may be the same as or different from the materials of some of CESL 66. In some embodiments, the hard mask layer 106 may be formed of a dielectric material having a high etching selectivity from the etching of the first ILD 72, such as silicon nitride, silicon oxide, silicon oxynitride, or the like, which may be formed by any suitable deposition process, such as CVD, ALD, or the like.

After the formation of the hard masks 102/106 and the pad layer 104, a photoresist layer may be formed and patterned (not shown). In some embodiments, a Bottom Anti-Reflective Coating (BARC, not shown) may also be formed between hard mask layer 106 and the patterned photo resist. In some embodiments, the hard mask layer 106 is etched using the patterned photoresist as an etching mask. An opening extends into hard mask layer 106 and exposes the top surface of the pad layer 104. The patterned photoresist may then be removed.

Further in FIGS. 6A and 6B, the pad layer 104, the underlying hard mask 102, the gate electrode 80, the ILD 68 and 72, the CESLs 70 and 66, and the isolation regions 32 are etched to form trench 110, which extends through the gate electrode 80 to expose the substrate 20. In some embodiments, the etching may be stopped to only partially etch into the isolation regions 32. In some embodiments, the etching may be continued further still until a portion of the substrate 20 is removed. The etching may include multiple cycles using various etchants effective for the removal of the different materials in the gate structure 90. In some embodiment, the bottom of the trench 110 may be disposed in the isolation regions 32 and may not penetrate the substrate 20. In some embodiments, the etching is performed using process gases selected from, and not limited to, Cl₂, BCl₃, Ar, CH₄, CF₄, and combinations thereof.

In the cross-sectional view of FIG. 6B, the trench 110 is formed to have a depth D1 from the bottom to the top, and to have and a width W1 at the bottom of the trench 110. In some embodiments, the aspect ratio (D1/W1) of the trench 110 in this cross-section is in a range from 10 to 30.

FIG. 6C illustrates a plan view of the trench 110 (with regions or portions 1110A and 110B) extending through the gate structures 90 between adjacent nanostructures 26. Reference line A-A′ of FIG. 6C illustrates the cross-section view of FIG. 6A, and reference line B-B′ of FIG. 6C illustrates the cross-section view of FIG. 6B.

In the illustrated embodiment, the trench 110 extends through three gate structures 90, and in other embodiments, the trench 110 may extend through more or less gate structures 90. The region 110B of the trench 110 will be used for the subsequently formed vertical interconnect structure 124/128/130 and the region 110A of the trench 110 does not contain the vertical interconnect structure. As shown in FIG. 6C, the region 110B is wider than the region 110A.

In FIGS. 7A and 7B, a dielectric layer 120 is formed in the bottom of the trenches 110 (and may also be referred to as bottom dielectric layer 120). The bottom dielectric layer 120 partially fills the trench 110 and lowers the aspect ratio of the trench 110. After the bottom dielectric layer 120 is formed, the remaining trench 110 has a depth D2 from the top surface of bottom dielectric layer 120 to the top, and has a width W2 at the top surface of bottom dielectric layer 120. In some embodiments, the aspect ratio (D2/W2) of the trench 110 after the bottom dielectric layer 120 is formed in the cross-section of FIG. 7B is in a range from 5 to 8.

The bottom dielectric layer 120 may be formed of a dielectric material such as silicon nitride, silicon oxide, silicon oxynitride, or the like, which may be formed by any suitable deposition process, such as CVD, ALD, or the like. In some embodiments, the dielectric constant (k-value) of the bottom dielectric layer 120 is in a range from 4 to 7. The bottom dielectric layer 120 may be a single layer or may include multiple layers including layers of different material compositions. For example, the bottom dielectric layer 120 may include a silicon nitride layer over a silicon oxide layer over a silicon nitride layer. In some embodiments, the bottom dielectric layer 120 is formed to have a thickness in a range from 50 nm to 100 nm. The bottom dielectric layer 120 may be selectively grown or formed in the trench 110 to have the desired thickness or the trench 110 may be filled and the bottom dielectric layer 120 is etched back to the desired thickness.

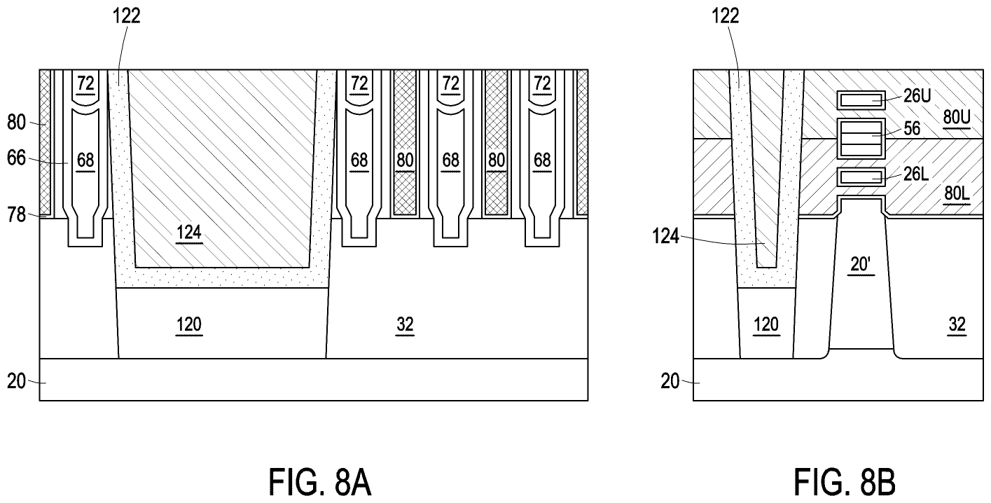

In FIGS. 8A and 8B, a liner 122 and a vertical interconnect 124 are formed in the remaining trench 110 on the bottom dielectric layer 120. In some embodiments, the liner 122 is a dielectric material and may include silicon oxide, silicon nitride, silicon oxynitride, silicon oxycarbonitride, or the like, which may be formed by a deposition process such as CVD, ALD, or the like. The liner 122 may include multiple layers such as a diffusion barrier layer, an adhesion layer, or the like. The diffusion barrier layer or the adhesion layer may include titanium, titanium nitride, tantalum, tantalum nitride, or the like. After the liner 122 is formed, a conductive material is formed in the opening to fill and overfill the remaining trench 110. The conductive material may be formed by a deposition process such as ALD, CVD, PVD, or the like. In some embodiments, the conductive material is cobalt, tungsten, palladium, nickel, aluminum, molybdenum, copper, silver, gold, the like, or combinations thereof. A planarization process, such as a CMP, may be performed to remove excess material from the top surfaces of the ILD 72 and the gate electrodes 80. The remaining conductive material forms the vertical interconnect 124 in the trench. The metal resistivity of the vertical interconnect 124 is less than 48 microhm-centimeters (μΩ·cm).

By having the bottom dielectric layer 120 the aspect ratio of the trench 110 is reduced, enabling the conductive material of the vertical interconnect 124 to be formed while avoiding a seam or void in the conductive material. Further, because vertical interconnect 124 extends through the stacking transistor in a cut metal gate area of the transistor, extra routing spacer for the vertical interconnect is not needed, thus reducing the overall size of the structure.

FIGS. 9A, 9B, and 9C illustrates cutting the vertical interconnect 124 to form a trench in the vertical interconnect 124 and fill the trench with dielectric material in accordance with some embodiments. The trench (not shown unfilled) in the vertical interconnect 124 may be formed in a similar manner as the trench 110 described above and the description is not repeated herein. For example, the trench may be formed using photolithography and etching step to form a trench that extends into the vertical interconnect 124. The cutting of the vertical interconnect 124 reduces the capacitance of the vertical interconnect 124 which can enable a higher operating speed for the device.

After the trench is formed, it is filled with dielectric material such as a dielectric liner 128 and a dielectric fill 130 on the dielectric liner 128. In some embodiments, the dielectric liner 128 may include silicon oxide, silicon nitride, silicon oxynitride, silicon oxycarbonitride, or the like, which may be formed by a deposition process such as CVD, ALD, or the like. After the dielectric liner 128 is formed, the dielectric fill 130 is formed in the opening to fill and potentially overfill the remaining trench. In some embodiments, the dielectric fill 130 may include silicon oxide, silicon nitride, silicon oxynitride, silicon oxycarbonitride, or the like, which may be formed by a deposition process such as CVD, ALD, or the like. In a specific embodiment, the dielectric liner 128 is silicon nitride and the dielectric fill is silicon oxide. A planarization process, such as a CMP, may be performed to remove excess dielectric material from the top surfaces of the vertical interconnect 124, ILD 72, and the gate electrodes 80. The remaining dielectric liner 128 and dielectric fill 130 forms the cut interconnect region 128/130 in the trench.

By replacing some of the conductive material of the vertical interconnect 124 with dielectric material of the cut dielectric region, the capacitance of the vertical interconnect 124 is reduced which can enable a higher operating speed for the device.

FIGS. 10A, 10B, and 10C illustrate the formation of metal-semiconductor alloy regions 138 and source/drain contacts 140 into the second ILD 72 to electrically couple to the upper epitaxial source/drain regions 62U and/or the vertical interconnect 124. As an example to form the source/drain contacts 140, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the source/drain contacts 140 in the openings.

As illustrated in FIG. 10C along reference line C-C′ of FIG. 1, the source/drain contact 140 can be butted contact and connect the vertical interconnect 124 and an upper epitaxial source/drain region 62U with a single source/drain contact 140. In some embodiments, the source/drain contact 140 extends through the CESL 70 into the ILD 68. Further, in some embodiments, the source/drain contact 140 extends along a sidewall and a top surface of an upper epitaxial source/drain region 62U. The vertical interconnect 124 can couple an upper epitaxial source/drain region 62U with a lower an epitaxial source/drain region 62L together with subsequently formed backside contact and interconnect structures.

Optionally, metal-semiconductor alloy regions 138 are formed at the interfaces between the source/drain regions 62 and the source/drain contacts 140. The metal-semiconductor alloy regions 138 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 138 can be formed before the material(s) of the source/drain contacts 96 by depositing a metal in the openings for the source/drain contacts 140 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 140, such as from surfaces of the metal-semiconductor alloy regions 138. The material(s) of the source/drain contacts 140 can then be formed on the metal-semiconductor alloy regions 138.

An ESL 134 and a third ILD 136 are formed. In some embodiments, the ESL 134 may include a dielectric material having a high etching selectivity from the etching of the third ILD 136, such as, aluminum oxide, aluminum nitride, silicon oxycarbide, or the like. The third ILD 136 may be formed using flowable CVD, ALD, or the like, and the material may include PSG, BSG, BPSG, USG, or the like, which may be deposited by any suitable method, such as CVD, PECVD, or the like.

In some embodiments, a planarization process such as a CMP, an etch-back process, combinations thereof, or the like is utilized. After the planarization process, the top surfaces of the third ILD 136, the ESL 134, and the source/drain contacts 96 are substantially coplanar (within process variations).

Gate contacts (not separately illustrated) may be formed to contact the upper gate electrodes 80U. As an example to form the gate contacts, openings for the gate contacts are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts in the openings. The gate contacts may be formed in distinct processes, or may be formed in the same process.

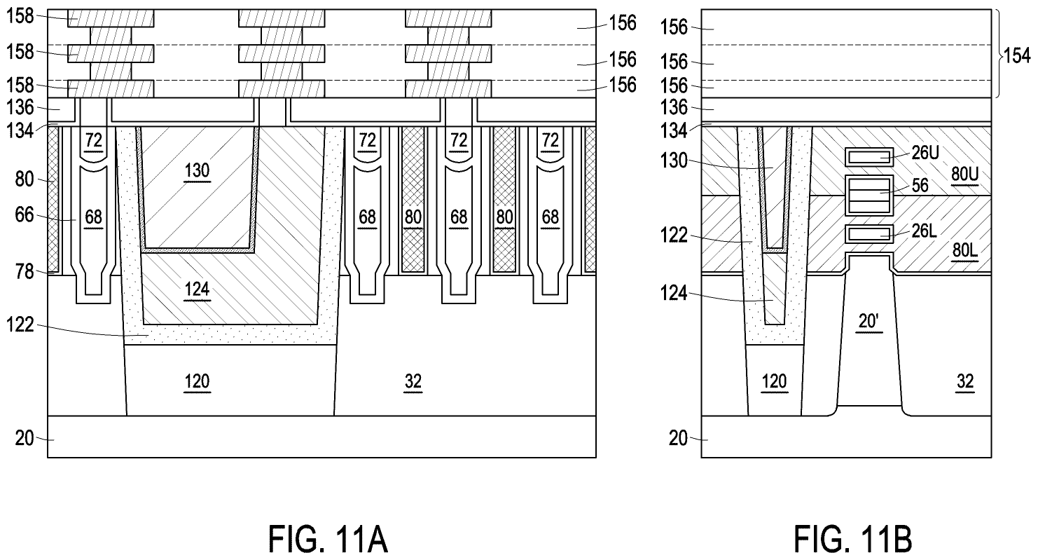

FIGS. 11A and 11B illustrate the formation of a front-side interconnect structure 154. The front-side interconnect structure 154 includes dielectric layers 156 and layers of conductive features 158 in the dielectric layers 156. The dielectric layers 156 may include low-k dielectric layers formed of low-k dielectric materials. The dielectric layers 156 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 156 may also include polymer layers.

The conductive features 158 may include conductive lines and vias, which may be formed using damascene processes. Conductive features 158 may include metal lines and metal vias, which includes diffusion barriers and a copper containing material over the diffusion barriers. The conductive features 158 may be electrically coupled to the contacts 140 and other underlying condutive features to provide routing and interconnection. There may also be aluminum pads over and electrically connected to the metal lines and vias. As will be discussed below, contacts to the lower gate structures 90L and the lower source/drain regions 62L may be made through a backside of the device (e.g., a side opposite to the front-side interconnect structure 154).

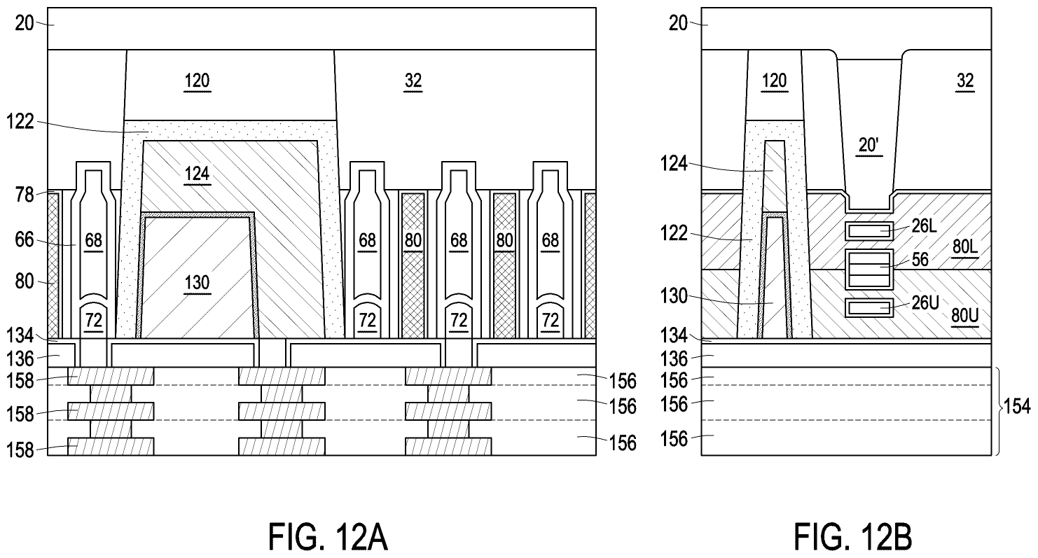

FIGS. 12A through 15B illustrate cross-sectional views of intermediate steps of forming backside vertical interconnect contacts in accordance with some embodiments. Referring to FIGS. 12A and 12B, an orientation of the device may be flipped. For example, a carrier substrate (not explicitly illustrated) may be bonded to the front-side interconnect structure 154 by dielectric-to-dielectric bonding, and the device may be flipped to expose a backside of the device (e.g., the side of the substrate 20 opposite to the front-side interconnect structure 154).

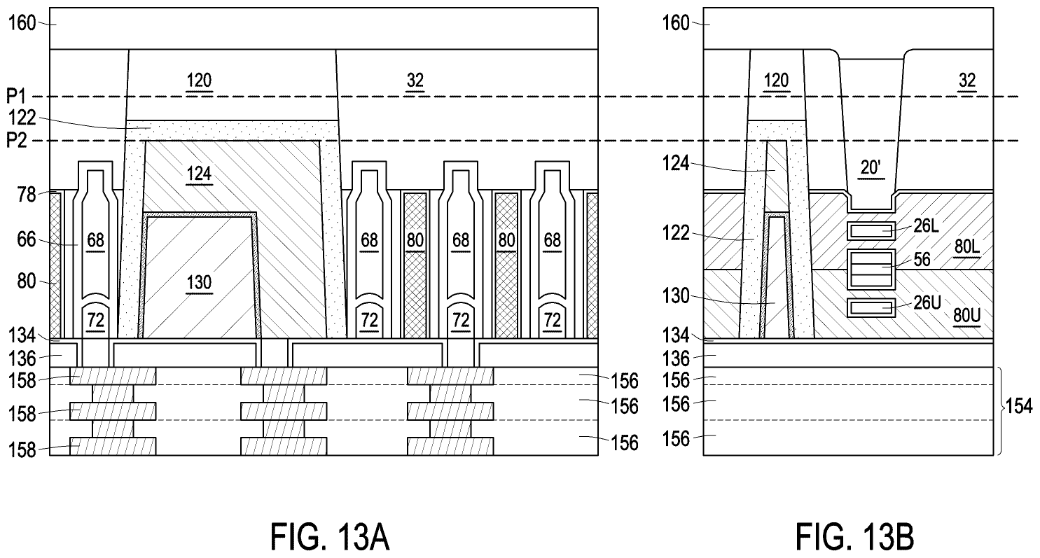

In FIGS. 13A and 13B, a substrate removal process may then be performed on the backside of the device (e.g., on the substrate 20). In some embodiments, the process may include a combination of CMP and/or etch-back processes, for example. The planarization process and/or etching processes may remove the substrate 20, exposing the semiconductor strips 20′ and may also simultaneously expose the STI regions 32 and/or the bottom dielectric layer 120. Removing the semiconductor substrate 20 and lower portions of the semiconductor strips 20′ advantageously improves electrical performance by improving isolation between subsequently formed backside gate contacts and/or backside source/drain contacts. For example, by removing the semiconductor substrate 20, concerns regarding backside contact shorting through the semiconductor substrate 20/semiconductor strips 20′ may be addressed.

After the lower portions of the semiconductor strips 20′ are removed, a backside dielectric layer 160, such as a backside oxide layer 160 is formed over the backside of the device and fills the opening in the STI region 32 where the semiconductor strips 20′ was removed. In some embodiments, the backside dielectric layer 160 is made of silicon oxide or the like. The backside dielectric layer 160 along with the bottom dielectric layer 120 enables subsequent planarization processes to remove these layers to expose the vertical interconnect 124 at the backside of the device without causing a protrusion or bump at the vertical interconnect 124.

FIGS. 14A, 14B, and 14C illustrate the planarization of the backside of the device to expose the vertical interconnect 124. In some embodiments, the planarization process includes multiple CMP steps or processes with a first CMP process stopping at reference line P1 in FIGS. 13A and 13B, and a second CMP process stopping at reference line P2 in FIGS. 13A and 13B. The first CMP process may stop at the semiconductor strip 20′ and the second CMP process may stop at the vertical interconnect 124.

In some embodiments, one or both of the CMP processes includes a ceria or silica-based CMP slurry for high dielectric throughput (SiOx or SixNy), and high oxide/silicon removal rate selectivity. This high selectivity allows for a precise CMP stop on the semiconductor strip 20′. After the planarization processes, the backside surfaces of the vertical interconnect 124, the liner 122, the STI regions 32, and the semiconductor strips 20′ are substantially coplanar (within process variations).

After the planarization processes are completed, the remaining semiconductor strip 20′ has a height H1. In some embodiments, the height H1 is in a range from 20 nm to 60 nm. Further, after the planarization processes are completed, the vertical interconnect 124 has a top width W3 and a bottom width W4 in FIG. 14C along the reference line C-C′ in FIG. 1. In some embodiments, the top width W3 is larger than the bottom width W4. In some embodiments, the top width W3 is in a range from 30 nm to 50 nm. In some embodiments, the bottom width W4 is in a range from 20 nm to 30 nm.

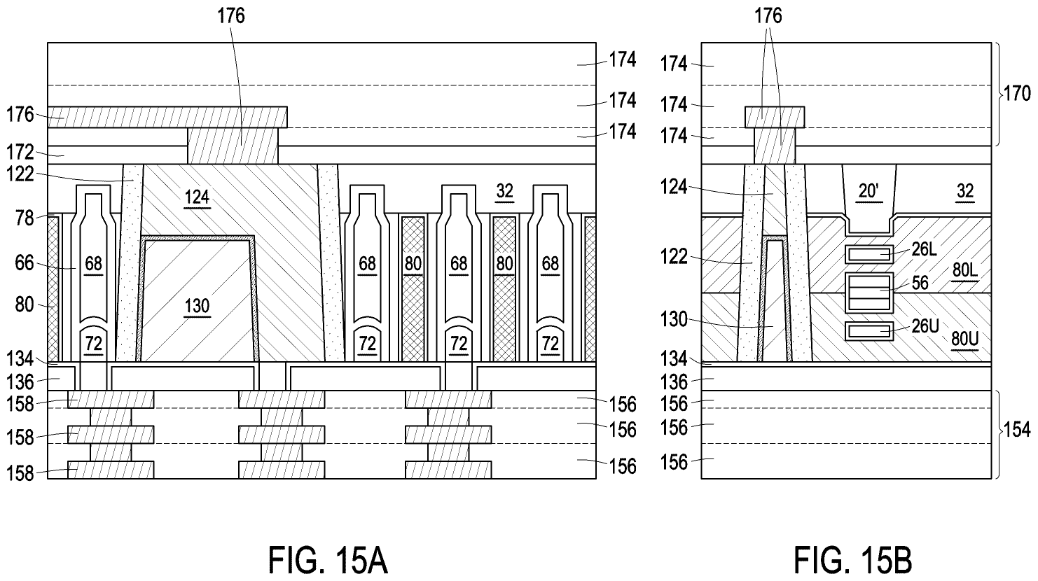

In FIGS. 15A and 15B, a backside interconnect structure 170 is formed. In some embodiments, a backside ESL 172 is deposited over a backside of the device, such as over the vertical interconnect 124, the STI regions 32, and the semiconductor strip 20′. The backside ESL 172 may be formed using similar materials and processes as the front side ESL 134 described above, and detailed description of the backside ESL 172 is not repeated herein. The backside ESL 172 may provide etching control during backside vertical interconnect contact formation. For example, the backside ESL 172 may provide endpoint control for patterning backside vertical interconnect contact openings that expose the vertical interconnect 124.

The backside interconnect structure 170 includes dielectric layers 174 and layers of conductive features 176 in the dielectric layers 174. The dielectric layers 174 may include low-k dielectric layers formed of low-k dielectric materials. The dielectric layers 174 may further include passivation layers, which are formed of non-low-k and dense dielectric materials such as USG, silicon oxide, silicon nitride, or the like, or combinations thereof over the low-k dielectric materials. The dielectric layers 174 may also include polymer layers.

The conductive features 176 may include conductive lines and vias, which may be formed using damascene processes. Conductive features 176 may include metal lines and metal vias, which includes diffusion barriers and a copper containing material over the diffusion barriers. The conductive features 176 may be electrically coupled to the vertical interconnect 124 and other underlying conductive features such as gate contacts and source/drain contacts (not separately illustrated) to provide routing and interconnection. There may also be aluminum pads over and electrically connected to the metal lines and vias.

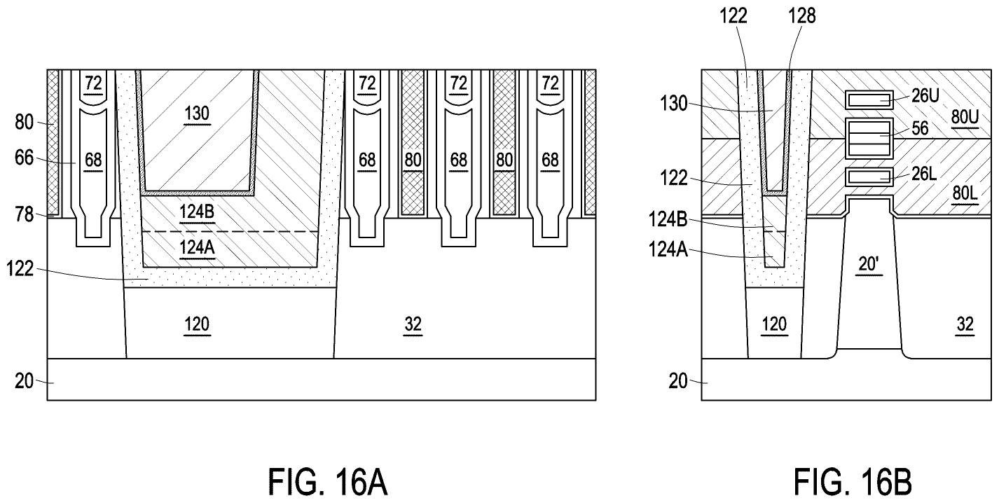

FIGS. 16A and 16B illustrate the cross-sectional views of intermediate stages in the formation of stacking transistors (as schematically represented in FIG. 1) in accordance with some embodiments. In FIGS. 16A and 16B, like reference numerals indicate like elements formed by like processes as described above in FIGS. 2 through 15B unless otherwise indicated. In FIGS. 16A and 16B, the vertical interconnect 124 includes two portions 124A and 124B with each portion being a different conductive material composition instead of a single conductive material composition through out the vertical interconnect 124. FIG. 16A illustrates a cross-sectional view along a similar cross-section as reference cross-section A-A′ in FIG. 1. FIG. 16B illustrates a cross-sectional view along a similar cross-section as reference cross-section B-B′ in FIG. 1.

FIGS. 16A and 16B illustrate a device in an intermediate stage of processing similar to the intermediate structure of FIGS. 9A, 9B, and 9C where like reference numerals indicate like elements formed by like processes.

In the embodiment of FIGS. 16A and 16B, the vertical interconnect 124 was formed of multiple conductive material compositions 124A and 124B. In some embodiments, the conductive material composition of the lower portion 124A is different than the conductive material composition of the upper portion 124B. In some embodiments, the lower and upper portions 124A and 124B are formed by different depositions processes. In some embodiments, the conductive material of the of the portions 124A and 124B may each include cobalt, tungsten, palladium, nickel, aluminum, molybdenum, copper, silver, gold, the like, or combinations thereof. In some embodiments, an interface is visible between the lower portion 124A and the upper portion 124B.

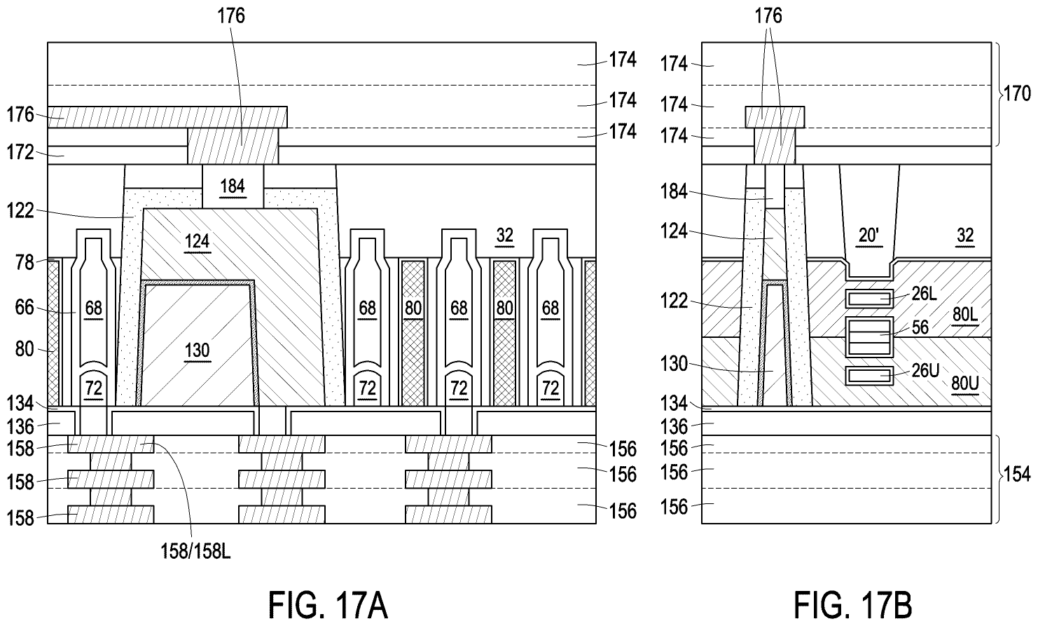

FIGS. 17A and 17B illustrate the cross-sectional views of intermediate stages in the formation of stacking transistors (as schematically represented in FIG. 1) in accordance with some embodiments. In FIGS. 17A and 17B, like reference numerals indicate like elements formed by like processes as described above in FIGS. 2 through 15B unless otherwise indicated. In FIGS. 17A and 17B, portions of the liner 122 and the bottom dielectric layer 120 remain on the backside of the device with a conductive via being formed through them to make electrical connection with the vertical interconnect 124 from the backside. FIG. 17A illustrates a cross-sectional view along a similar cross-section as reference cross-section A-A′ in FIG. 1. FIG. 17B illustrates a cross-sectional view along a similar cross-section as reference cross-section B-B′ in FIG. 1.

FIGS. 17A and 17B illustrate a device in an intermediate stage of processing similar to the intermediate structure of FIGS. 15A and 15B where like reference numerals indicate like elements formed by like processes.

In the embodiment of FIGS. 17A and 17B, during the removal of the backside dielectric layer 160 (see, e.g., FIGS. 13A through 14B), the removal stops at the semiconductor strip 20′ (see, e.g. reference line P1 in FIGS. 13A and 13B). In this embodiment, the remaining portion of the bottom dielectric layer 120 and the liner 122 are not removed, and a backside conductive via 184 is formed through the bottom dielectric layer 120 and the liner 122 to provide backside electrical connection to the vertical interconnect 124. The backside conductive via 184 may be formed by similar materials and processes as the conductive features in the interconnects 154 and 170 and the description is not repeated herein.

After the formation of the conductive via 184, processing similar to those described in FIGS. 15A and 15B may be performed to achieve the structure in FIGS. 17A and 17B.

In an embodiment, a semiconductor device may include a plurality of first nanostructures. The plurality of first nanostructures extend between first source/drain regions. The semiconductor device may also include a plurality of second nanostructures over the plurality of first nanostructures. The plurality of second nanostructures extend between second source/drain regions. The device may furthermore include a first gate stack around the plurality of first nanostructures. The device may in addition include a second gate stack over the first gate stack and disposed around the plurality of second nanostructures. The device may moreover include a vertical interconnect structure extending through the first and second gate stacks. The device may also include a frontside contact electrically coupled to a frontside of the vertical interconnect structure and a backside contact electrically coupled to a backside of the vertical interconnect structure.

The described embodiments may also include one or more of the following features. The semiconductor device where the vertical interconnect structure extends through more than two gate stacks. The semiconductor device where the vertical interconnect structure electrically couples one of the first source/drain regions to one of the second source/drain regions. The semiconductor device may include a dielectric liner on sidewalls of the vertical interconnect structure. The vertical interconnect structure having a conductive material. The semiconductor device may include a backside dielectric layer on the backside of the vertical interconnect structure. The backside contact extending through the backside dielectric layer. The semiconductor device where outer sidewalls of the backside dielectric layer are coterminous with outer sidewalls of the dielectric liner. The semiconductor device where the vertical interconnect structure may include a first region extending from the frontside of the vertical interconnect structure into the vertical interconnect structure. The first region having a dielectric material. The semiconductor device where the frontside contact is a butted contact electrically coupling the vertical interconnect structure to one of the second source/drain regions. The semiconductor device where the vertical interconnect structure may include a lower portion and an upper portion. The lower portion having a different material composition than the upper portion. Each of the lower and upper portions being conductive. The semiconductor device may include a frontside interconnect structure electrically coupled to the frontside contact and a backside interconnect structure electrically coupled to the backside contact.

In an embodiment, a method may include forming a first transistor and a second transistor over a semiconductor substrate. The first transistor and the second transistor being vertically stacked. The method may also include removing a first gate stack of the first transistor and a second gate stack of the second transistor. The removing forming a first trench. The method may furthermore include forming a first dielectric layer in the first trench, depositing a conductive material over the first dielectric layer, etching a second trench in the conductive material, forming a second dielectric layer in the second trench. The conductive material being between the first and second dielectric layers and forming a frontside conductive contact on a frontside of the conductive material. The frontside conductive contact being electrically coupled to the conductive material and a source/drain of the second transistor.

The described embodiments may also include one or more of the following features. The method may include forming a backside conductive contact on a backside of the conductive material. The method may include removing the semiconductor substrate to expose a backside of the conductive material and forming a backside conductive contact on a backside of the conductive material. The method may include removing the semiconductor substrate and exposing a backside of a shallow trench isolation (STI) region, forming an oxide layer on the backside of the STI region, performing a first planarization step to remove the oxide layer and at least a portion of the first dielectric layer in the first trench, performing a second planarization step to remove a remaining portion of the first dielectric layer in the first trench and exposing a backside of the conductive material in the first trench, and forming a backside conductive contact on the exposed backside of the conductive material. The method may include removing the semiconductor substrate and exposing a backside of a shallow trench isolation (STI) region, forming an oxide layer on the backside of the STI region, performing a first planarization step to remove the oxide layer and at least a portion of the first dielectric layer in the first trench, and forming a backside conductive contact through a remaining portion of the first dielectric layer in the first trench. The backside conductive contact being electrically coupled to a backside of the conductive material. The method may include after forming the first dielectric layer in the first trench, depositing a dielectric liner on sidewalls and a bottom surface of the first trench over the first dielectric layer. The conductive material being on the dielectric liner. The method where outer sidewalls of the first dielectric layer are coterminous with outer sidewalls of the dielectric liner.

In an embodiment, a method may include forming a multi-layer stack over a semiconductor substrate. The multi-layer stack having alternating semiconductor nanostructures and dummy nanostructures. The method may also include forming lower source/drain regions where lower semiconductor nanostructures of the semiconductor nanostructures extend between the lower source/drain regions. The method may furthermore include forming upper source/drain regions over the lower source/drain regions where upper semiconductor nanostructures of the semiconductor nanostructures extend between the upper source/drain regions. The method may in addition include replacing the dummy nanostructures with a lower gate stack around the lower semiconductor nanostructures and an upper gate stack around the upper semiconductor nanostructures. The method may moreover include etching a first trench through the upper gate stack and the lower gate stack, forming a bottom dielectric layer in a bottom of the first trench, forming a conductive interconnect on the bottom dielectric layer in the first trench, forming a second trench in the conductive interconnect, forming a dielectric material in the second trench, forming a frontside conductive contact on a frontside of the conductive interconnect, and forming a backside conductive contact on a backside of the conductive interconnect. The frontside and backside conductive contacts being electrically coupled to the conductive interconnect.

The described embodiments may also include one or more of the following features. The method where the frontside conductive contact is electrically coupled to the conductive interconnect and one of the upper source/drain regions. The method may include removing the semiconductor substrate to expose a backside of the conductive interconnect.

Various embodiments provide a stacking transistor of two vertically stacked transistors, and a vertical interconnect structure extending through the stacking transistor. The vertical interconnect structure allows for backside interconnect routing and can reduce the need and size of the frontside interconnect. The vertical interconnect structure extends through the stacking transistor in a cut metal gate area of the transistor. Further, the vertical interconnect structure can include a cut region to reduce replace some of the conductive material of the vertical interconnect with dielectric material to reduce the capacitance and enable a higher operating speed for the device. In some embodiments, the vertical interconnect structure can couple drain regions of the stacking transistor.

The vertical interconnect structure includes a metal interconnect structure and a bottom dielectric structure that reduces the aspect ratio of the metal interconnect structure and avoids a seam or void in the metal interconnect structure. Further, the disclosed embodiments include a backside planarization process to expose the metal interconnect of the vertical interconnect structure without causing the metal interconnect to protrude from the backside. Thus, the disclosed embodiments provide a vertical interconnect structure without metal protrusion from the backside. As a result, the disclosed embodiments allow for improved process integration, increased routing flexibility, and increased device performance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a plurality of first nanostructures, the plurality of first nanostructures extending between first source/drain regions;
a plurality of second nanostructures over the plurality of first nanostructures, the plurality of second nanostructure extending between second source/drain regions;
a first gate stack around the plurality of first nanostructures;
a second gate stack over the first gate stack and disposed around the plurality of second nanostructures;
a vertical interconnect structure extending through the first and second gate stacks;
a frontside contact electrically coupled to a frontside of the vertical interconnect structure; and
a backside contact electrically coupled to a backside of the vertical interconnect structure.

2. The semiconductor device of claim 1, wherein the vertical interconnect structure extends through more than two gate stacks.

3. The semiconductor device of claim 1, wherein the vertical interconnect structure electrically couples one of the first source/drain regions to one of the second source/drain regions.

4. The semiconductor device of claim 1, further comprising:
a dielectric liner on sidewalls of the vertical interconnect structure, the vertical interconnect structure comprising a conductive material.

5. The semiconductor device of claim 4, further comprising a backside dielectric layer on the backside of the vertical interconnect structure, the backside contact extending through the backside dielectric layer.

6. The semiconductor device of claim 5, wherein outer sidewalls of the backside dielectric layer are coterminous with outer sidewalls of the dielectric liner.

7. The semiconductor device of claim 1, wherein the vertical interconnect structure comprises a first region extending from the frontside of the vertical interconnect structure into the vertical interconnect structure, the first region comprising a dielectric material.

8. The semiconductor device of claim 1, wherein the frontside contact is a butted contact electrically coupling the vertical interconnect structure to one of the second source/drain regions.

9. The semiconductor device of claim 1, wherein the vertical interconnect structure comprises a lower portion and an upper portion, the lower portion having a different material composition than the upper portion, each of the lower and upper portions being conductive.

10. The semiconductor device of claim 1 further comprising:
a frontside interconnect structure electrically coupled to the frontside contact; and
a backside interconnect structure electrically coupled to the backside contact.

11. A method comprising:
forming a first transistor and a second transistor over a semiconductor substrate, the first transistor and the second transistor being vertically stacked;
removing a first gate stack of the first transistor and a second gate stack of the second transistor, the removing forming a first trench;
forming a first dielectric layer in the first trench;
depositing a conductive material over the first dielectric layer;
etching a second trench in the conductive material;
forming a second dielectric layer in the second trench, the conductive material being between the first and second dielectric layers; and
forming a frontside conductive contact on a frontside of the conductive material, the frontside conductive contact being electrically coupled to the conductive material and a source/drain of the second transistor.

12. The method of claim 11, further comprising:
forming a backside conductive contact on a backside of the conductive material.

13. The method of claim 11, further comprising:
removing the semiconductor substrate to expose a backside of the conductive material; and
forming a backside conductive contact on a backside of the conductive material.

14. The method of claim 11, further comprising:
removing the semiconductor substrate and exposing a backside of a shallow trench isolation (STI) region;
forming an oxide layer on the backside of the STI region;
performing a first planarization step to remove the oxide layer and at least a portion of the first dielectric layer in the first trench;
performing a second planarization step to remove a remaining portion of the first dielectric layer in the first trench and exposing a backside of the conductive material in the first trench; and
forming a backside conductive contact on the exposed backside of the conductive material.

15. The method of claim 11, further comprising:
removing the semiconductor substrate and exposing a backside of a shallow trench isolation (STI) region;
forming an oxide layer on the backside of the STI region;
performing a first planarization step to remove the oxide layer and at least a portion of the first dielectric layer in the first trench; and
forming a backside conductive contact through a remaining portion of the first dielectric layer in the first trench, the backside conductive contact being electrically coupled to a backside of the conductive material.

16. The method of claim 11, further comprising:
after forming the first dielectric layer in the first trench, depositing a dielectric liner on sidewalls and a bottom surface of the first trench over the first dielectric layer, the conductive material being on the dielectric liner.

17. The method of claim 16, wherein outer sidewalls of the first dielectric layer are coterminous with outer sidewalls of the dielectric liner.

18. A method comprising:
forming a multi-layer stack over a semiconductor substrate, the multi-layer stack comprising alternating semiconductor nanostructures and dummy nanostructures;
forming lower source/drain regions, wherein lower semiconductor nanostructures of the semiconductor nanostructures extend between the lower source/drain regions;
forming upper source/drain regions over the lower source/drain regions, wherein upper semiconductor nanostructures of the semiconductor nanostructures extend between the upper source/drain regions;
replacing the dummy nanostructures with a lower gate stack around the lower semiconductor nanostructures and an upper gate stack around the upper semiconductor nanostructures;
etching a first trench through the upper gate stack and the lower gate stack;
forming a bottom dielectric layer in a bottom of the first trench;
forming a conductive interconnect on the bottom dielectric layer in the first trench;
forming a second trench in the conductive interconnect;
forming a dielectric material in the second trench;
forming a frontside conductive contact on a frontside of the conductive interconnect; and
forming a backside conductive contact on a backside of the conductive interconnect, the frontside and backside conductive contacts being electrically coupled to the conductive interconnect.

19. The method of claim 18, wherein the frontside conductive contact is electrically coupled to the conductive interconnect and one of the upper source/drain regions.

20. The method of claim 18, further comprising:
removing the semiconductor substrate to expose a backside of the conductive interconnect.
